(19) United States
(12) Patent Application Publication
(10) Pub. No.: US 2013/0034970 A1
(43) Pub. Date: Feb. 7, 2013

(54) PLASMA PROCESSING METHOD

(71) Applicant: Hiroyuki Takaba, Tokyo (JP)

(72) Inventor: Hiroyuki Takaba, Tokyo (JP)

(73) Assignee: TOKYO ELECTRON LIMITED, Tokyo (JP)

(21) Appl. No.: 13/196,052

(22) Filed: Aug. 2, 2011

(51) Int. Cl. H01L 21/263

(52) U.S. Cl. 438/798; 257/E21.331

(57) ABSTRACT

A method for forming a fluorocarbon layer using a plasma reaction process includes the step of applying a microwave power and an RF bias. The microwave power and the RF bias are applied under a pressure ranging from 20 mTorr to 60 mTorr.

This application claims priority from U.S. provisional application Ser. No. 61/207,973, filed Feb. 17, 2009, entitled “Plasma Processing Method”, the contents of which is incorporated herein by reference in its entirety.

### TECHNICAL FIELD

The present invention relates to semiconductor devices and their manufacturing methods. More specifically, it relates to a fluorocarbon (CFx) forming process for improving the adhesiveness of CFx layer with other metal or insulating layers while maintaining a low value of permittivity for the fluorocarbon (CFx) layer.

### BACKGROUND OF THE INVENTION

In recent years, multilayer wiring structures have been employed to achieve high speed operation and miniaturization of semiconductor devices. However, these structures have raised the problem of wiring delay due to an increase in the overall wiring resistance and parasitic capacitance of the wiring layers.

The use of low resistance wiring material, e.g., copper (Cu), as the interconnection body reduces the wiring resistance. On the other hand, low permittivity or low-k materials may be used to reduce the parasitic capacitance. Specially, fluorine added carbon (fluorocarbon: CFx) may be used as the insulating layer to reduce parasitic capacitance then to improve the operating speed of semiconductor devices.

A conventional plasma reaction process is used for forming a fluorocarbon (CFx) layer with a low-permittivity. The plasma reaction process is performed using a microwave plasma treatment device in which the plasma is generated by exciting a plasma gas, e.g., argon (Ar) or krypton (Kr), using a microwave from an external microwave source. The deposition process is made using a plasma enhanced chemical vapor deposition (PE-CVD) method when a CF-series process gas such as, for example, C₅F₈ or C₆F₆ gas is introduced into a plasma region maintained under a pressure of at least about 50 mTorr. This provides a higher film forming speed with regards to the etching speed for forming the fluorocarbon (CFx) layer.

However, the fluorocarbon (CFx) formed under the above-mentioned forming condition, using only one energy source, e.g., microwave plasma, as the plasma excitation source, may provide unfavorable results with regards to the insulating properties and the desorption gas characteristics of the CFx layer. As a result, the adhesiveness of the CFx layer with the surface of other layers such as, for example, metals or insulating layers, may deteriorate at the time of deposition.

The present invention is proposed in view of the above aforementioned problems. The present invention provides a process for forming a fluorocarbon (CFx) layer with superior insulating properties and desorption gas characteristics while maintaining a low value of permittivity.

### SUMMARY OF THE INVENTION

In accordance with one aspect of the present invention, there is provided a method for forming a fluorocarbon (CFx) insulating layer. The method includes the step of applying a microwave power and an RF bias under a pressure of not less than 20 mTorr and not more than 60 mTorr.

In accordance with a second aspect of the present invention, there is provided a method for forming a fluorocarbon (CFx) insulating layer. The method includes the step of applying a microwave power and an RF bias with a pressure under which the fluorocarbon layer does not deposit without applying the RF bias, wherein the pressure is not less than 20 mTorr.

In accordance with a third aspect of the present invention, there is provided a method for manufacturing semiconductor devices having a fluorocarbon layer as an insulating layer. The method includes the step of forming the fluorocarbon layer over a substrate using a plasma reaction process. The forming step is performed when a microwave power and an RF bias are applied under a pressure ranging from 20 mTorr to 60 mTorr.

In accordance with a forth aspect of the present invention, there is provided a method for forming a fluorocarbon layer using a plasma reaction process. The method includes the steps of applying a microwave power and an RF bias; and introducing oxygen (O) into a processing chamber in addition to a plasma excitation gas and a CF-series process gas.

### BRIEF DESCRIPTION OF THE DRAWINGS

FIG. 1 illustrates schematically an example of deposition rate as a function of pressure in a plasma reaction process.

FIG. 2 illustrates schematically dielectric constant curve of a fluorocarbon (CFx) layer as function of pressure.

FIG. 3 depicts a schematic diagram of an embodiment of an insulating layer forming device.

FIG. 4 illustrates target structure and a plan view of an experimental sample with its stress test results.

FIG. 5 illustrates contour maps used for measuring the thickness and refractive index of CFx4 samples.

FIG. 6 illustrates cross-sectional views of CFx experimental samples used for evaluating their surface morphology.

FIG. 7 illustrates leakage current as a function of applied field for various experimental samples.

FIG. 8 illustrates TDS intensity of various experimental samples.

FIG. 9 illustrates TDS intensity of various experimental samples.

FIG. 10 illustrates leakage current as function of RF bias for various experimental samples.

FIG. 11 illustrates leakage current as function of fluorocarbon layer thickness for various experimental samples.

FIG. 12 illustrates relative permittivity as function of pressure for various experimental samples.

FIG. 13 illustrates an average relative permittivity as function of pressure for various experimental samples.

FIG. 14 illustrates contour maps of an alternative embodiment.

FIG. 15 illustrates relative permittivity of various experimental samples as a function of refractive index.

### DETAILED DESCRIPTION OF INVENTION

Embodiments of the present invention will be described hereinafter with reference to the accompanying drawings, in which preferred exemplary embodiments of the invention are shown. The ensuing description is not intended to limit the scope, applicability or configuration of the disclosure. Rather, the ensuing description of the preferred exemplary embodiments will provide those skilled in the art with an enabling description for implementing preferred exemplary embodiments of the disclosure. It should be noted that this invention may be embodied in different forms without departing from the spirit and scope of the invention as set forth in the appended claims.

This disclosure relates in general to semiconductor devices and their manufacturing process. More specifically, it relates to a new fluorocarbon (CFx) forming process for improving the adhesiveness of CFx layer with other metal or insulating layers while maintaining a low value of permittivity for the CFx layer.

Embodiments of the present invention are directed to a process for forming a fluorocarbon (CFx) insulating layer with enhanced insulating properties and desorption gas characteristics to improve the adhesiveness of the CFx layer while maintaining a low value of permittivity (k: less than about 2.3). This is achieved by selecting a predetermined process condition where the fluorocarbon (CFx) layer may not be deposited without applying an RF bias with a microwave plasma power. In this way, the forming speed of the fluorocarbon deposition process is increased while the etching speed of the process is reduced.

By selecting the predetermined process condition, the compositional ratio of a reactive byproduct, the conventional fluorocarbon (CFx) generated by the microwave plasma power, may be minimized. In addition, the predetermined process condition allows the majority of microwave plasma to excite the plasma gas, e.g., argon (Ar) gas, and also to maintain the plasma conditions. On the other hand, the relative permittivity of the fluorocarbon (CFx) insulating layer is not adversely affected by the presence of the RF bias if the RF bias is applied within a few hundred watts.

Moreover, when a high-frequency (RF) bias is applied for forming a fluorocarbon (CFx) insulating layer, a compositional ratio of carbon to fluorine (C/F) is about 0.9 to 1.0. This is contrary to the conventional results where the fluorocarbon (CFx) layer is formed without applying the high-frequency RF bias, where the compositional ratio of carbon to fluorine (C/F) is about 1.1 to 1.2. Taking into account the adhesiveness of the fluorocarbon (CFx) insulating layer with a barrier layer mainly composed of a metal element, such as, for example, titanium (Ti), it is more preferable to use the fluorocarbon (CFx) forming process of the present invention.

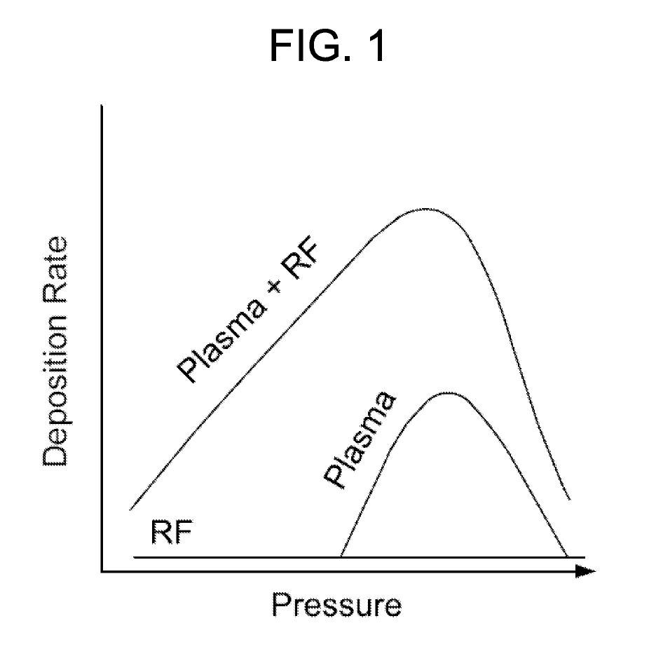

Referring first to FIG. 1, an example of deposition rate as a function of pressure is shown schematically in a plasma reaction process. As shown in this figure, the deposition rate is shown as a function of pressure for two energy sources: 1) a plasma excitation source, e.g., microwave power source, and 2) a high-frequency (RF) power source. It should be noted that when the plasma excitation source, microwave power source, is used as the only energy source, the deposition occurs when the pressure of the plasma gas is maintained at or above about 30 mTorr. However, as described previously, the fluorocarbon (CFx) layer formed under the above-mentioned condition does not show favorable results with regards to the insulating properties and the desorption gas characteristics of the CFx layer, despite its low permittivity (k<˜2.3).

By applying a high-frequency (RF) power source, in addition to the microwave power source, the deposition may occur when the pressure of the plasma gas is maintained at a pressure ranging from about 20 mTorr to 60 mTorr. As shown in FIG. 1, this pressure region is roughly divided into two sub-regions: 1) the first sub-region with a pressure ranging from 20 mTorr to 30 mTorr and 2) the second sub-region with a pressure ranging from 30 mTorr to 60 mTorr. The first sub-region, also called “an etching plasma region”, is a region where the deposition may not occur without applying the high-frequency (RF) power in combination with the microwave power source. The second sub-region is a region where the deposition may occur without applying the high-frequency (RF) power, by applying the microwave power source as the only energy source. However, the addition of high-frequency (RF) power allows for forming fluorocarbon (CFx) layers with superior insulating properties and desorption gas characteristics while maintaining a low value of permittivity. These favorable results are also provided when forming fluorocarbon (CFx) layers in the etching plasma region (a pressure of 20 mTorr to 30 mTorr).

When forming a fluorocarbon (CFx) layer in the above-mentioned pressure region, the fluorocarbon (CFx) etching speed may be reduced in addition to increase of the fluorocarbon forming speed. Since the forming speed and the etching speed in the plasma reaction process are directly related to the microwave power source, the microwave power source is set to generate a microwave power ranging from about 1 kW to 3.5 kW at a frequency of 2.45 GHz.

Furthermore, as described previously, the Fluorocarbon (CFx) layer formed in the above-mentioned pressure region provides favorable insulating properties and desorption gas characteristics. To achieve these favorable results, the RF power source is applied at a frequency of about 400 kHz with an RF power ranging from about 20 W to 120 W.

According to one aspect of present invention, the relative permittivity of fluorocarbon (CFx) layer is not adversely affected by the presence of the RF bias source. However, as will be described further below, the fluorocarbon (CFx) layer with a relative permittivity of less than about 2.3 can be achieved when the pressure region is limited to a predetermined range.

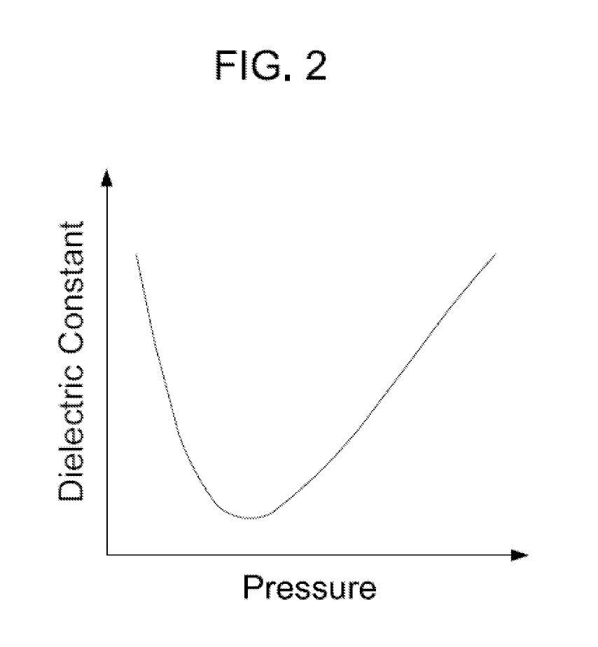

Referring next to FIG. 2, the dielectric constant curve of a fluorocarbon (CFx) layer as function of pressure is schematically shown. The fluorocarbon (CFx) insulating layer according to the embodiments of the present invention may be deposited by applying the RF power source in addition to the microwave power source, when the pressure of the plasma gas is maintained at or below 60 mTorr. However, as shown in FIG. 2, the relative permittivity of the CFx layer tends to increase when the pressure becomes too low. This is mainly due to the fact that the amount of process gas, e.g., CF-series gas, that reacts with the generated plasma is relatively increased when the pressure of the plasma gas and the microwave power are low. As a result, the relative permittivity of the fluorocarbon (CFx) layer is increased when the pressure of the plasma gas becomes too low.

To avoid the increase of relative permittivity of the CFx insulating layer formed according to the process of present invention, it is preferable that pressure of the plasma gas being maintained within a predetermined range. In the preferred embodiment, the predetermined range of the pressure is set to be within 20 mTorr to 60 mTorr, which is the same pressure range as the one used for obtaining fluorocarbon (CFx) layers with superior insulating properties and desorption gas characteristics.

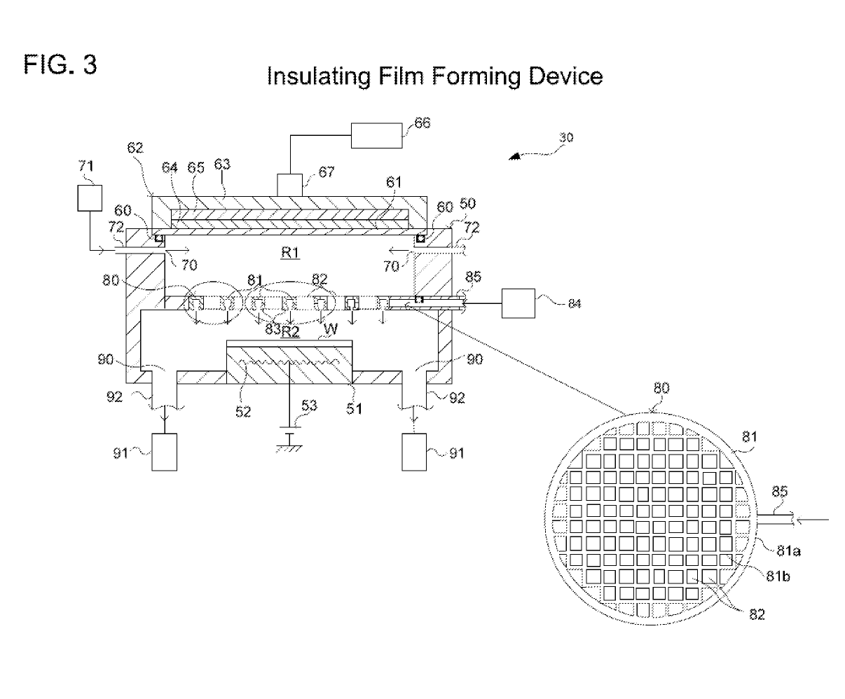

The fluorocarbon (CFx) insulating layer according to the preferred embodiment of the present invention is formed using an insulating layer forming device. FIG. 3 illustrates a schematic diagram of an embodiment of an insulating layer forming device 30. As shown in this figure, the insulating layer forming device 30 includes a process vessel 50, a radial line slot antenna 62, and a mounting table 51.

Inside of the process vessel 50 is sectionalized into a plasma generation region R1 at the radial line slot antenna 62 side and a film formation region R2 at the mounting table 51 side. An external microwave source 66 provides a microwave power of a predetermined frequency, e.g., 2.45 GHz, to the radial line slot antenna 62. The microwave from the microwave source 66 causes excitation of a plasma gas, e.g., argon (Ar) gas, released into the plasma generation region R1 from gas supply ports 70. The plasma gas is supplied from a plasma gas supply source 71 to the gas supply ports 70, via gas rings 72, which is then released into the plasma generation region R1.

The insulating layer forming device 30 further includes a process gas supply structure 80, also called shower plate 80. The plan view of the process gas supply structure 80 is also shown in FIG. 3. The process gas supply structure 80 includes process gas supply pipes 81, disposed in between the plasma generation region R1 and the film forming region R2 as a grid facing the substrate W mounted on the mounting table 51. The process gas supply pipes 81 may include an annular pipe 81a and a grid pipe 81b. The annular pipe 81a is disposed annularly at an outer peripheral portion of the process gas supply structure 80. The grid pipe 81b is disposed such that a plurality of matrix pipes is orthogonal with each other at an inner side of the annular pipe 81a.

At a lower surface of the process gas supply structure 80, a number of process gas supply ports 83 are formed uniformly over the substrate W. A process gas supply source 84 is connected to the process gas supply pipes 81 through a gas pipe 85. In this embodiment, the process gas supply source 84 provides a mixture of argon (Ar) gas and a CF-series process gas, e.g., C₅F₈, as a diluted gas, to the process gas supply pipes 81 via the gas pipe 85. The diluted gas is then discharged downwardly from the respective process gas supply ports 83 toward the film forming region R2. The flow rate of a gas, e.g., CF-series gas, may be divided into two rates: 1) “sh-c” flow rate and 2) “sh-e” flow rate, depending on the location of process gas supply ports 83 on the shower plate 80. The “sh-c” flow rate refers to the process gas supply ports 83 located at the center of the shower plate 80. On the other hand, the “sh-e” flow rate refers to the process gas supply ports 83 located at the edge portion of the shower plate 80.

### Experimental Samples

In order to evaluate insulating properties, the adhesion, and also the reliable operation of fluorocarbon (CFx) insulating layer, several experimental samples are manufactured according to the process described in the present disclosure. The experimental samples are then subjected to different tests for evaluating the above-mentioned properties. In each of the experimental samples a fluorocarbon (CFx4) insulating layer is formed by applying the high-frequency RF power source and the microwave plasma source. Unless described otherwise below, the following setting conditions are used to form the following fluorocarbon layers: 1) CFx4 layers; a microwave power of about 1 kW to 3.5 kW at a frequency of 2.45 GHz, a high-frequency RF power of about 20 W to 120 W at a frequency of 400 kHz, 2) CFx2 layers; a microwave power of about 1.5 kW at a frequency of 2.45 GHz, without applying any high-frequency RF bias and formed under a low pressure, less than 30 mTorr and 3) CFx layers; a microwave power of about 3 kW at a frequency of 2.45 GHz, without applying any high-frequency RF bias and formed under a pressure of about 50 mTorr. All the experimental samples with different fluorocarbon (CFx, CFx2, and CFx4) insulating layers are formed at a substrate temperature of about 330° C. to 400° C. In the following the results of these evaluations will be explained in detail.

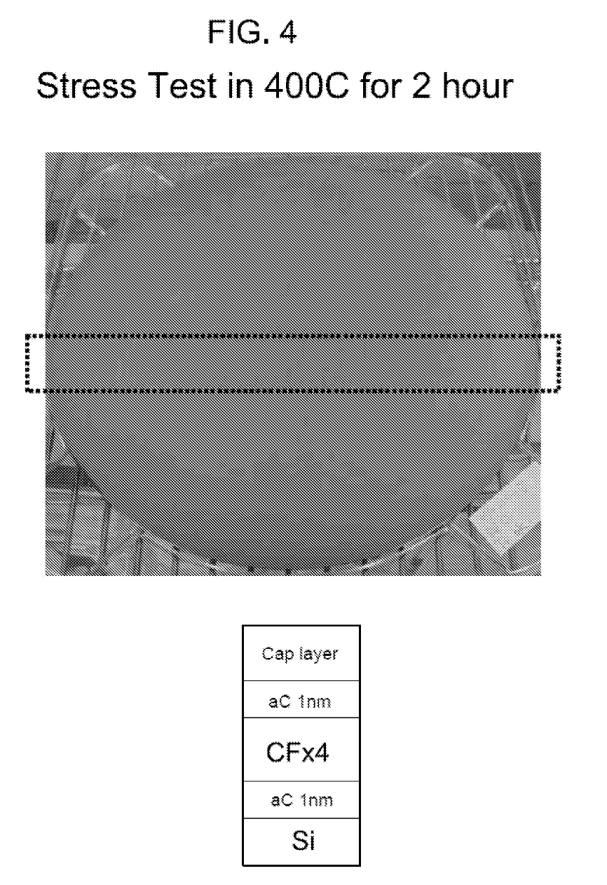

With reference to FIG. 4, a target structure and a plan view of an experimental sample used for performing the stress test, the tape test, and the blister test is shown. The structure used for these evaluations includes a first amorphous carbon layer, a fluorocarbon (CFx4) layer, a second amorphous carbon layer, and a hermetic cap layer. The first amorphous carbon layer is formed on a bulk silicon (Si) substrate while the second amorphous carbon layer is formed over the fluorocarbon (CFx4) layer. Both amorphous carbon layers have a thickness of about 10 nm and are formed in the etching plasma region where a high-frequency (RF) bias, from an external RF power source 53 (please refer to FIG. 3), is applied to the substrate W mounted on the mounting table 51 of the insulating layer forming device 30. The RF bias has a frequency of 400 kHz with an RF power of about 120 W. The fluorocarbon (CFx4) layer is also formed under the same forming condition in the etching plasma region. Therefore, the same RF bias source, as the one used for forming the amorphous carbon layers, is applied to the substrate W. The hermetic cap layer is formed to react with desorption gas generated from the CFx4 layer.

A pre-evaluation annealing is then performed at a temperature of about 350° C. for a period of 24 hours. After performing the pre-evaluation annealing, the experimental sample is subjected respectively to the stress test, the blister test, and the tape test. The stress test is conducted at a temperature of about 400° C. for a period of 2 hours. This experimental sample passed the stress test at all deposition layers, amorphous carbon layers and the CFx4 layer. A plan view of the experimental sample after adhering scotch tape to its surface is also shown in FIG. 4. Similar to the stress test, all the layers formed in the etching plasma region with applied RF bias passed the blister test and the tape test. This means that no blisters and peeling-off of the layers were observed for this sample.

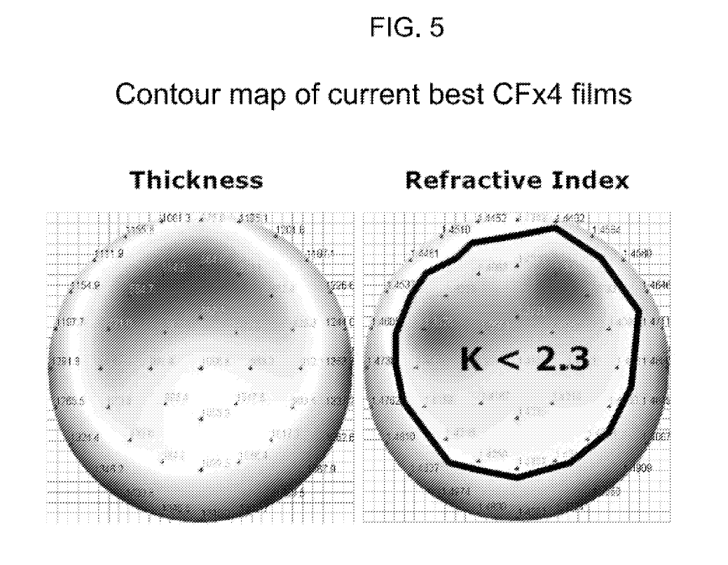

In the following, the refractive index and the thickness of fluorocarbon (CFx4) layers formed according to the process of the present invention are investigated. For this purpose several experimental samples were manufactured, however only the current best CFx4 samples are chosen to be used in this evaluation. FIG. 5 illustrates contour maps of current best experimental samples used for measuring the refractive index and the thickness of fluorocarbon (CFx4) layers. Table I summarizes the average value, the minimum value, the maximum value, and the non-uniformity value obtained from the contour maps with regards to the thickness and the refractive index of the experimental samples.

TABLE I
Thickness and refractive index of CFx4 experimental samples

| | Thickness (nm) | Refractive Index |
|---|---|---|
| Average (Ave) | 105.78 | 1.4404 |
| Maximum (Max) | 143.95 | 1.506 |
| Minimum (Min) | 55.49 | 1.3591 |
| Non-uniformity (NU) | 22.85 | 2.5616 |

As shown in FIG. 5 and also summarized in Table I, the non-uniformity issue with regards to the thickness and refractive index of fluorocarbon (CFx4) samples is still present despite the new fluorocarbon forming process. However, the refractive index and thereby the relative permittivity remains low (k<˜2.3) over the entirety of fluorocarbon (CFx4) experimental samples.

In what follows, the surface morphology of fluorocarbon (CFx) insulating layers, formed according to the process of the present invention, is investigated. For this purpose, two experimental samples with different fluorocarbon (CFx and CFx4) layers are formed over a bulk silicon substrate. Both CFx and CFx4 samples are formed with the same setting conditions as those described in paragraph [0027] using the insulating layer forming device 30.

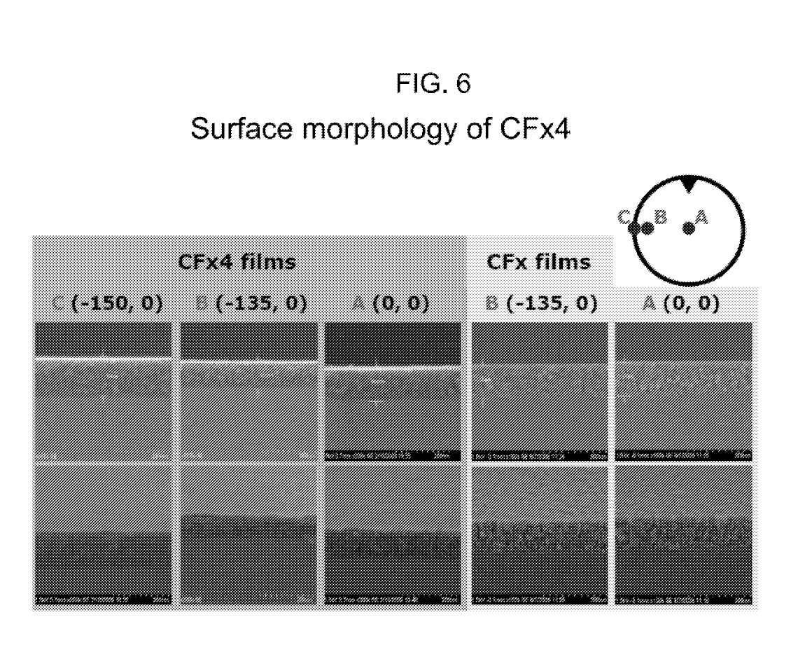

Referring next to FIG. 6, cross-sectional views of two experimental samples, taken from different points compared to the center of their respective wafers, are shown. The cross-sectional views of both experimental samples are shown in the upper and lower side of FIG. 6. For the CFx experimental sample, the cross-sectional views are taken at two points with following coordinates: 1) A(0, 0) and 2) B(−135, 0). On the other hand, the cross sectional-views of the CFx4 experimental sample are taken at three points where the first two points have the same coordinates as the one used for the CFx sample (A(0, 0), B(−135, 0)), while the third point has the following coordinates C(−150, 0). As shown in FIG. 6, the experimental sample with the CFx4 insulating layer has less dents and raises compared to the experimental sample with CFx insulating layer. Therefore, the surface morphology of CFx4 insulating layer is improved compared to the case of CFx layer. As a result, a smoother surface for the CFx4 insulating layer is obtained.

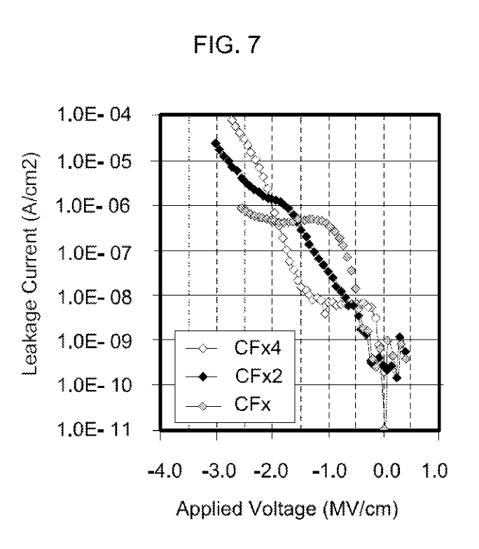

With reference to FIG. 7, the leakage current as a function of applied field is shown for various experimental samples. The leakage current is measured at a point of thermal stress where a heat treatment is conducted at a temperature of about 400° C. for a period of 2 hours. Three experimental samples; CFx, CFx2, and CFx4, are formed for this evaluation. It should be noted that both CFx and CFx2 insulating layers are formed without applying any high-frequency RF bias. The CFx insulating layer is formed under a pressure of about 50 mTorr while the CFx2 insulating layer is formed under a low pressure (less than 30 mTorr). The high-frequency RF bias is applied for forming the experimental sample with CFx4 insulating layer under the same condition as those described in paragraph [0027].

As shown in FIG. 7, the experimental sample with the CFx4 insulating layer has a lower leakage current when the applied voltage is within a range of about −2 MV/cm to −0.5 MV/cm. Table II summarizes the value of leakage current (Jg@1.5 MV/cm) for each experimental sample when the applied electric field is about 1.5 MV/cm. As shown in Table II, the CFx4 insulating layer has a lower leakage Current value at 1.5 MV/cm.

TABLE II
Leakage current value at 1.5 MV/cm applied voltage

| Experimental Sample | Jg@1.5 MV/cm |
|---|---|
| CFx4 | 1.9 × 10⁻⁸ |
| CFx2 | 3.4 × 10⁻⁷ |
| CFx | 4.5 × 10⁻⁷ |

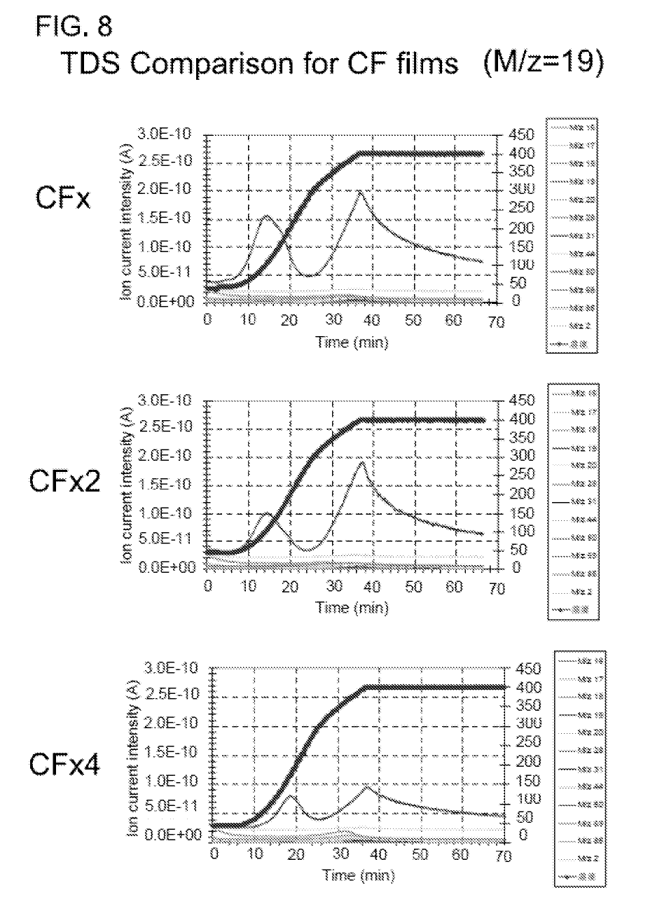

Three experimental samples (CFx, CFx2, and CFx4) are formed according to the fluorocarbon forming process of the present invention and then subjected to the thermal desorption spectroscopy (TDS) measurement. This experiment is performed to detect the molecular weight or atomic weight of fluorine (F) in each experimental sample. A thermal desorption spectroscopy of each sample is measured and the results are shown in FIG. 8. The vertical axis is the measured-value intensity of fluorine (F) gas at a mass of 19 (M/z=19) and the horizontal axis is the processing time during which the temperature is increased at a predetermined rate. In this experiment, fluorine (F) gas with the mass of 19 is detected. In the spectrums shown in FIG. 8, there are two peaks P₁ and P₂. Table III summarizes the intensity of both peaks for each experimental sample. As shown in FIG. 8 and also in Table III, the CFx4 insulating layer has a lower degassing rate of fluorine at the mass of 19 (M/z=19).

TABLE III
Intensity of first and second peaks of for each experimental sample

| M/z = 19 Intensity (a.u.) | 1^{st} Peak (P₁) | 2^{nd} Peak (P₂) |
|---|---|---|
| CFx | 1.55 × 10⁻¹⁰ | 1.95 × 10⁻¹⁰ |
| CFx2 | 9.92 × 10⁻¹⁰ | 1.91 × 10⁻¹⁰ |
| CFx4 | 7.90 × 10⁻¹¹ | 9.47 × 10⁻¹¹ |

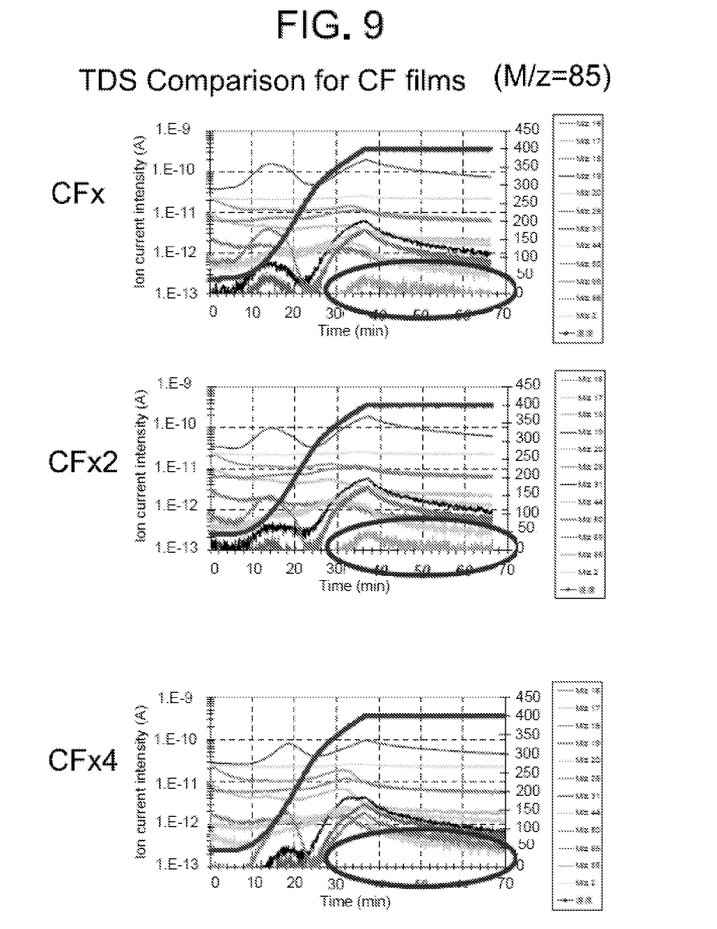

In next experiment the degassing or desorption gas attributed to the SiF3 with a molecular weight of 85 (M/z=85) is investigated. For this purpose, the thermal desorption spectroscopy of three samples (CFx, CFx2, and CFx4) is measured and the results are shown in FIG. 9. Similar to the previous experiment, shown in FIG. 8, the vertical axis is the measured-value intensity of SiF3 gas at a mass of 85 (M/z=85) and the horizontal axis is the processing time during which the temperature is increased at a predetermined rate. In this experiment, SiF3 gas with the mass of 85 is detected. One peak is observed in the spectrums of FIG. 9. Table IV summarizes the peak intensity for each experimental sample. As shown in FIG. 9 and also in Table IV, the SiF3 peak was not observed at CFx4 insulating layer. Therefore, the degas amount ascribed to SiF3 of CFx4 layer is the smallest amount within the three experimental samples.

TABLE IV
Intensity peak of SiF3 for each experimental sample

| M/z = 85 Intensity (a.u.) | Peak |
|---|---|
| CFx | 3.02 × 10⁻¹³ |
| CFx2 | 3.37 × 10⁻¹³ |
| CFx4 | Under Detection Limit |

In the following, the setting condition used for forming our best current fluorocarbon (CFx4) experimental samples will be described in detail. Table V summarizes the setting conditions for forming our best current CFx4 samples.

TABLE V
Setting condition used for forming CFx4 insulating layer

| Setting Condition | CFx4 |
|---|---|
| Pressure (mTorr) | 22 |
| Microwave Power (kW) | 1.2 |
| RF Bias (W) | 120 |
| Processing Time (Sec) | 145 |
| C₅F₈ flow rate Center/edge (sccm) | 100/71 |
| Ar flow rate Center/edge/ring (sccm) | 10/10/30 |
| Temperature (° C.) | 350 |

The experimental results for our current best CFx4 insulating layer are also summarized in Table VI.

TABLE VI
Experimental results of CFx4 insulating layer

| | | | Relative | | |
|---|---|---|---|---|---|
| | Thickness | Refractive | Permittivity | Jg@1 M/cm | Jg@1.5 M/cm |
| | (nm) | Index | (k) | (A/cm²) | (A/cm²) |
| Average (Ave) | 149.28 | 1.4988 | 2.33 | 6.84 × 10⁻⁹ | 1.87 × 10⁻⁸ |
| Maximum (Max) | 172.79 | 1.564 | — | — | — |
| Minimum (Min) | 117.18 | 1.4247 | — | — | — |
| Non-uniformity | 10.87 | 3.03419 | — | — | — |
| (NU) | | | | | |

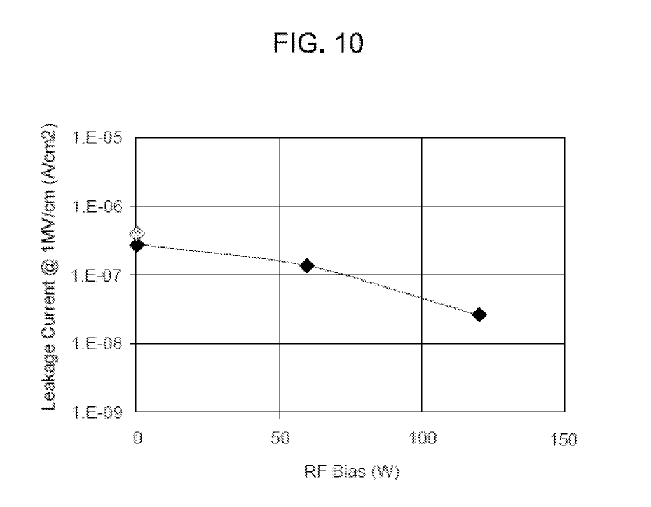

Referring next to FIG. 10, the leakage current as a function of RF bias is shown for four experimental samples. All the experimental samples were manufactured using the film forming process of the present invention with the setting conditions as described in paragraph [0027]. Three experimental samples with the CFx4 insulating layers were formed where the RF bias was respectively set at the following powers: 0 W, 60 W, and 120 W. The fourth experimental sample includes a CFx layer as the insulating layer and the RF power was set to 0 W for this sample. As shown in FIG. 10, the leakage current tends to decrease when the RF bias power increases. It should be noted that the leakage current values are measured when the applied voltage is set to 1 MV/cm (Jg@1 MV/cm).

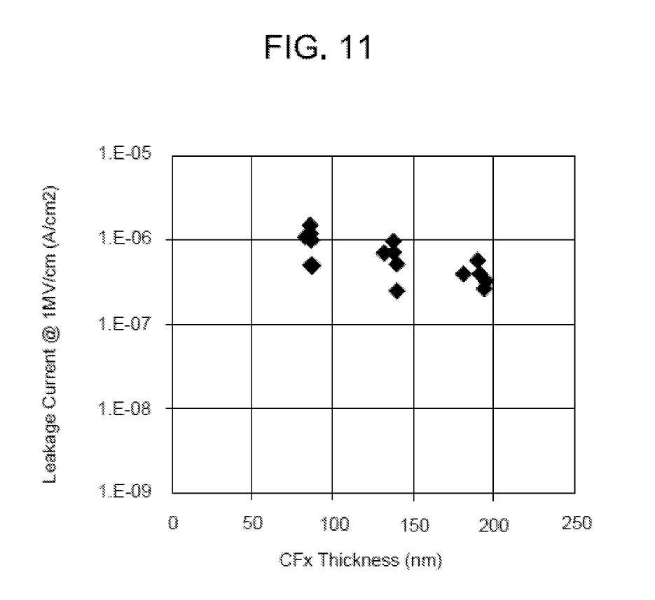

FIG. 11 illustrates the leakage current as a function of fluorocarbon (CFx4) layer thickness. For this purpose, three set of experimental samples were manufactured. In each set, five experimental samples with approximately the same fluorocarbon (CFx4) thickness layer were formed. The average thickness of fluorocarbon (CFx4) insulating layer for the first, second, and third set of experimental samples are respectively 85.49 nm, 137.11 nm, and 190.26 nm. As shown in FIG. 11, the thicker the fluorocarbon (CFx4) insulating layer is, the lower is the value of the leakage current. It should be noted that the leakage current values are measured when the applied voltage is set to 1 MV/cm (Jg@1 MV/cm).

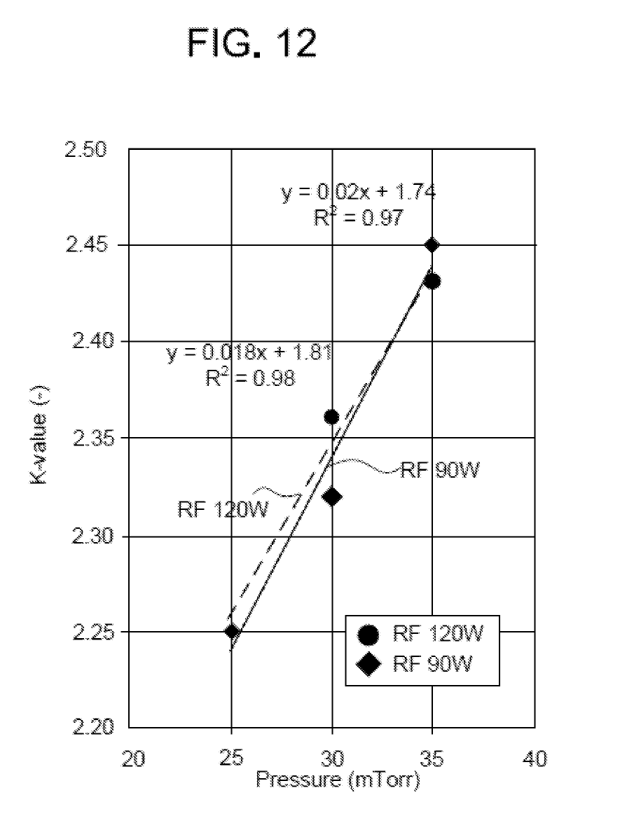

Referring next to FIG. 12, the relative permittivity of fluorocarbon (CFx4) layer as a function of pressure is shown for various experimental samples. For this evaluation, two set of experimental samples were formed using the insulating layer forming device 30. In each set, three experimental samples are formed under the following pressures: 25 mTorr, 30 mTorr, and 35 mTorr. The RF bias in the first and second set is respectively set to 90 W and 120 W. The measurement results of relative permittivity are shown in FIG. 12. As shown in this figure, the higher the setting condition for pressure, the higher is the value of relative permittivity. Using a linear regression, a best fit linear approximation is calculated for each set of data. As shown in FIG. 12, a very good correlation (RF bias: 90 W→²=0.97 and RF bias: 120 W→R²=0.98) is obtained for each set of experimental samples.

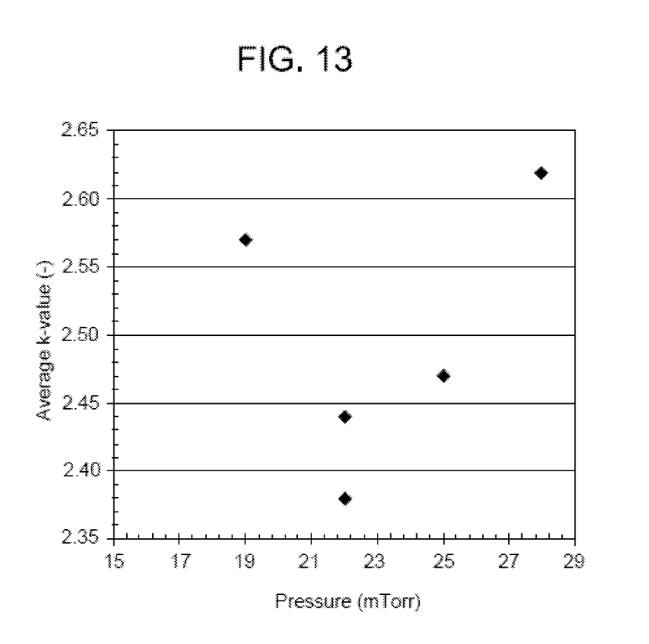

The average relative permittivity as a function of pressure is shown in FIG. 13 for various experimental samples. As shown in this figure, the minimum average value of 2.38 is obtained at a pressure of 22 mTorr, while the maximum average value of 2.62 is obtained at a pressure of 28 mTorr. According to this result, the pressure value of 22 mTorr provides the lowest value of relative permittivity. This means that the best value of pressure used for forming fluorocarbon (CFx4) insulating layers is about 22 mTorr.

In the following, an alternative embodiment is evaluated to improve even further the properties of the fluorocarbon (CFx4) insulating layer. In this alternative embodiment, oxygen (O) is introduced through the gas ring 72 into the process vessel 50 of the insulating layer forming device 30. To evaluate the effectiveness of this alternative embodiment, two experimental samples (#1 and #2) with exactly the same setting conditions, except for the oxygen (O) gas, are manufactured. Table VII summarizes the setting conditions for both experimental samples. As discussed previously, “sh-c”, “sh-e”, represent respectively the flow rate of a gas at the center and edge of the shower plate 80, while “gr” represent the flow rate of the gas at the gas rings 72.

TABLE VII
Setting conditions used for forming experimental samples

| | | | | | | O | C₅F₈ | C₅F₈ | Ar | Ar | Ar |
|---|---|---|---|---|---|---|---|---|---|---|---|
| Exp. | RF | MW | Temp. | Press. | Time | gr | sh-c | sh-e | sh-c | sh-e | gr |
| sample | (W) | (W) | (° C.) | (mTorr) | (sec) | (sccm) | (sccm) | (sccm) | (sccm) | (sccm) | (sccm) |
| #1 | 60 | 3000 | 350 | 60 | 35 | 0 | 140 | 100 | 90 | 30 | 30 |
| #2 | 60 | 3000 | 350 | 60 | 35 | 28 | 140 | 100 | 90 | 30 | 30 |

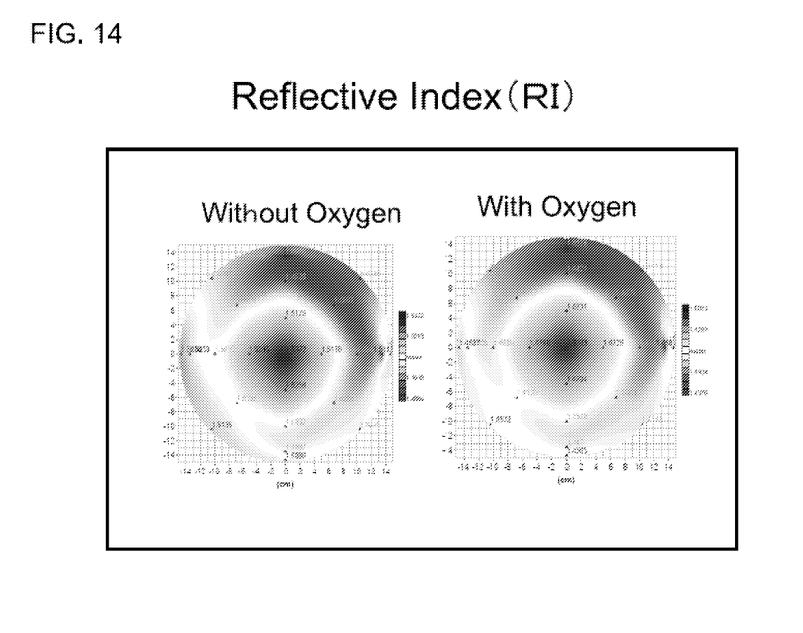

With reference to FIG. 14, contour maps of both experimental samples used for measuring the refractive index are shown. As shown in this figure, the maximum, minimum, and average values of refractive index are lower for the experimental sample #2 where the oxygen (O) gas is added into the atmosphere on the process vessel 50. This results in a lower permittivity (low-k) for the second experimental sample. Table VIII summarizes the thickness, the refractive index, and the relative permittivity (k) of both experimental samples. As shown in this Table, the thickness value and the relative permittivity (k) are also lower when the oxygen is added into the atmosphere. This evaluation confirms that a lower value of permittivity may be obtained using oxygen (O).

TABLE VIII
Measurement results for both experimental samples

| | Thickness | Non-uniformity | | | k-value |
|---|---|---|---|---|---|
| Exp. | (nm) | Thickness | | | (1 MV |
| samples | (Thx_ave) | (1sigma) | RI_min | RI_max | Ave) |
| #1 | 147.02 | 3.56% | 1.4886 | 1.5372 | 2.13-2.35 |
| #2 | 107.93 | 6.16% | 1.4376 | 1.5023 | 2.04-2.15 |

In what follows the operating reliability of fluorocarbon (CFx, CFx2, CFx4) insulating layers is investigated. For this purpose, three set of experimental samples each having different fluorocarbon (CFx, CFx2, CFx4) insulating layer is manufactured. In each set, three identical samples with similar fluorocarbon (CFx, CFx2, or CFx4) insulating layers are formed over silicon (Si) bulk substrates. The setting conditions for forming the fluorocarbon (CFx, CFx2, and CFx4) insulating layers in each set of experimental sample are summarized in Table VIV.

TABLE VIV
Setting conditions used for each set of experimental sample.

| Exp. | | | | N₂ | N₂ | C₅F₈ | C₅F₈ | Ar | Ar | Ar |
|---|---|---|---|---|---|---|---|---|---|---|
| sample | RF | MW | Press. | sh-c | sh-e | sh-c | sh-e | sh-c | sh-e | gr |
| set | (W) | (W) | (mTorr) | (sccm) | (sccm) | (sccm) | (sccm) | (sccm) | (sccm) | (sccm) |
| #1 | 0 | 3000 | 48 | 0 | 0 | 140 | 100 | 90 | 30 | 30 |
| (CFx) | | | | | | | | | | |
| #2 | 0 | 1450 | 28 | 0 | 0 | 116 | 84 | 20 | 20 | 40 |
| (CFx2) | | | | | | | | | | |
| #3 | 25 | 1350 | 23 | 10 | 10 | 106 | 84 | 20 | 30 | 30 |
| (CFx4) | | | | | | | | | | |

To evaluate the operating reliability of fluorocarbon (CFx, CFx2, and CFx4) insulating layers, the experimental samples of each set are subjected to an accelerated test, also called “Mist bath”, for evaluation. Therefore, after forming the fluorocarbon (CFx, CFx2, or CFx4) insulating layers of each set, the experimental samples of each set are put into a constant temperature, e.g., 80° C., at a high humidity bath, e.g., 85% (H₂O). To conduct our experiment, the first sample of each set is not subjected to the accelerated test. Then, the second sample of each set is subjected to the accelerated test by putting the experimental sample into the Mist bath for a period of 1 to 10 minutes. The last experimental sample in each set is also subjected to the accelerated test for a period of 100 minutes.

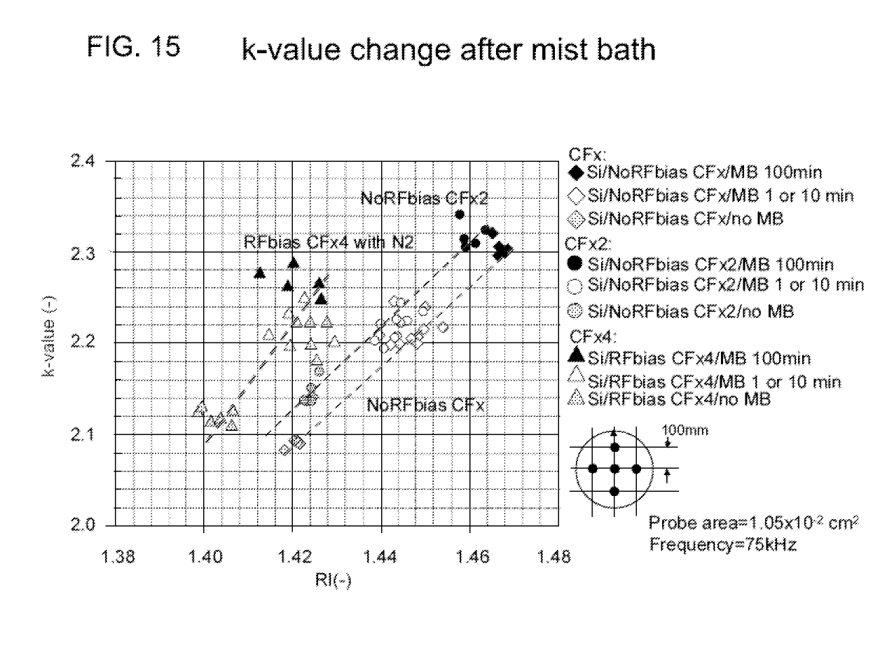

FIG. 15 illustrates relative permittivity (k-value) as a function of refractive index for each set of experimental sample. It is known that the smaller is the change in refractive index of an insulating layer, kept at a constant temperature in a high humidity environment, the better is their insulating properties and therefore their overall reliabilities.

As shown in FIG. 15, the smallest change in refractive index and therefore in the relative permittivity is occurred in the third set of experimental samples. As shown in Table VIV, the fluorocarbon (CFx4) insulating layers of the third set of experimental sample are formed by applying an RF bias and also by adding nitrogen (N₂) gas into the atmosphere. By adding nitrogen (N₂) into the atmosphere, the nitrogen (N₂) atoms get excited, thereby emitting light toward the surface of the CFx4 insulating layer. This results in a curing or modifying effect on the fluorocarbon (CFx) insulating layer, which leads in turn to a smaller variation in refractive index and consequently in relative permittivity.

While the principles of the disclosure have been described above in connection with specific apparatuses and methods, it is to be clearly understood that this description is made only by way of example and not as limitation on the scope of the invention.

What is claimed is:

1. A method for forming a fluorocarbon layer using a plasma reaction process, the method comprising the step of:
applying a microwave power and an RF bias under a pressure of not less than 20 mTorr and not more than 60 mTorr.

2. The method as recited in claim 1, wherein a power of the RF bias is not less than 20 W and not more than 120 W.

3. The method as recited in claim 1, wherein the microwave power is not less than 1.0 kW and not more than 3.5 kW.

4. The method as recited in claim 3, wherein a frequency of the microwave is about 2.45 GHz.

5. The method as recited in claim 1, wherein a frequency of the RF bias is about 400 kHz.

6. The method as recited in claim 1, wherein the fluorocarbon layer comprises CFx4.

7. A method for forming a fluorocarbon layer using a plasma reaction process, the method comprising the step of:
applying a microwave power and an RF bias with a pressure under which the fluorocarbon layer does not deposit without applying the RF bias, wherein the pressure is not less than 20 mTorr.

8. The method as recited in claim 7, wherein a power of the RF bias is not less than 20 W and not more than 120 W.

9. The method as recited in claim 7, wherein the pressure is not more than 30 mTorr.

10. The method as recited in claim 7, wherein the microwave power is not less than 1.0 kW and not more than 3.5 kW.

11. The method as recited in claim 10, wherein a frequency of the microwave is about 2.45 GHz.

12. The method as recited in claim 7, wherein a frequency of the RF bias is about 400 kHz.

13. The method as recited in claim 7, wherein the fluorocarbon layer comprises CFx4.

14. A method for manufacturing a semiconductor device having a fluorocarbon layer as an insulating layer, the method comprising the step of:
forming the fluorocarbon layer over a substrate using a plasma reaction process,
wherein a microwave power and an RF bias are applied under a pressure ranging from 20 mTorr to 60 mTorr during said forming step.

15. The method as recited in claim 14, wherein a power of the RF bias is not less than 20 W and not more than 120 W.

16. The method as recited in claim 14, wherein the microwave power is not less than 1.0 kW and not more than 3.5 kW with a frequency of about 2.45 GHz.

17. The method as recited in claim 14, wherein a frequency of the RF bias is about 400 kHz.

18. A method for forming a fluorocarbon layer using a plasma reaction process, the method comprising the steps of;
applying a microwave power and an RF bias;
introducing oxygen (O) into a processing chamber in addition to a plasma excitation gas and a CF— series process gas.

19. The method as recited in claim 18, wherein a power of the RF bias is not less than 20 W and not more than 120 W.

20. The method as recited in claim 18, wherein the microwave power and the RF bias are applied under a pressure of not less than 20 mTorr and not more than 60 mTorr.
